(19) United States
(12) Patent Application Publication
(10) Pub. No.: US 2025/0164583 A1
(43) Pub. Date: May 22, 2025

(54) MAGNETIC SENSOR AND MAGNETIC MEASUREMENT METHOD

(71) Applicant: Alps Alpine Co., Ltd., Tokyo (JP)

(72) Inventors: Eiji UMETSU, Niigata-ken (JP); Kanta KIKUCHI, Niigata-ken (JP); Tomoyuki SAWATAISHI, Miyagi-ken (JP); Kazufumi NAGANUMA, Miyagi-ken (JP)

(21) Appl. No.: 19/024,160

(22) Filed: Jan. 16, 2025

Related U.S. Application Data
(63) Continuation of application No. PCT/JP2023/008380, filed on Mar. 6, 2023.

(30) Foreign Application Priority Data
Aug. 9, 2022 (JP) 2022-126853

(51) Int. Cl. G01R 33/00; G01R 33/09; H10N 50/10

(52) U.S. Cl. CPC G01R 33/0029; G01R 33/093; H10N 50/10; G01R 33/098

(57) ABSTRACT

A magnetic sensor includes a magnetic detection unit including a magnetoresistance effect element having a pinned magnetic layer, a free magnetic layer, and an intermediate layer formed between the pinned magnetic layer and the free magnetic layer, a magnetic field calculation unit configured to calculate a measurement magnetic field based on an output of the magnetic detection unit, and a saturation magnetic field application unit configured to apply a magnetic field to the free magnetic layer in a direction of the measurement magnetic field to magnetically saturate the free magnetic layer. The magnetic field calculation unit calculates the measurement magnetic field based on a first output of the magnetic detection unit when the measurement magnetic field is applied to the free magnetic layer, and a second output of the magnetic detection unit when the free magnetic layer is magnetically saturated.

### CLAIM OF PRIORITY

This application is a Continuation of International Application No. PCT/JP2023/008380 filed on Mar. 6, 2023, which claims benefit of Japanese Patent Application No. 2022-126853 filed on Aug. 9, 2022. The entire contents of each application noted above are hereby incorporated by reference.

### BACKGROUND OF THE INVENTION

### 1. Field of the Invention

The present invention relates to a magnetic sensor including a magnetoresistance effect element and a magnetic measurement method.

### 2. Description of the Related Art

Some magnetic sensors for detecting and measuring magnetic fields include a magnetoresistance effect element that uses the giant magnetoresistance (GMR) effect or the tunnel magnetoresistance (TMR) effect. The magnetoresistance effect element in such magnetic sensors includes a pinned magnetic layer, a non-magnetic intermediate layer, and a free magnetic layer, which are stacked in this order. In the magnetoresistance effect element, the magnetization direction of the free magnetic layer changes when an external magnetic field, which is a measurement target, is applied, and this change causes a resistance change according to the angle between the magnetization direction of the free magnetic layer and the magnetization direction of the pinned magnetic layer. These magnetic sensors including such a magnetoresistance effect element can detect a magnetic field by using the resistance change in the magnetoresistance effect element.

The magnetic sensors including the magnetoresistance effect element have 1/f noise that cannot be removed by filters. Since 1/f noise is inversely proportional to frequency and increases at lower frequencies, such 1/f noise may inhibit highly accurate measurements. Accordingly, various methods are used to remove 1/f noise.

Japanese Unexamined Patent Application Publication No. 2018-115972 discloses a magnetic sensor that removes 1/f noise by calculating, in an even function type magnetic sensor, the difference between an output when a bias magnetic field is applied in a direction (+X direction) and an output when a bias magnetic field is applied in the opposite direction (−X direction).

Japanese Unexamined Patent Application Publication No. 2020-148727 discloses a measurement device in which when a Hall electromotive force of a semiconductor sample is measured, the frequency band of a voltage difference Vm is shifted to the lower frequency side to remove noise due to a Schottky barrier generated between the electrode and the sample, and the frequency band of the voltage difference Vm, which is greatly affected by 1/f noise, is removed.

PCT Japanese Translation Publication No. 2012-518788 discloses a magnetic field sensing device that samples bridge signals in each of a first current and a second current by switching two sampling holds and determines the value of the magnetic field from the difference between the sampled first and second bridge signals.

PCT Japanese Translation Publication No. 2009-544004 discloses a sensor device that switches the positive and negative of a sensor signal using a modulator and calculates the difference between the modulated signals to remove 1/f noise in an output signal.

### SUMMARY OF THE INVENTION

In these magnetic sensors including such a magnetoresistance effect element, 1/f noise in the low frequency range reduces the detection accuracy of the magnetic sensors, and to solve the problem, various devices and methods have been proposed. The present invention has been made to provide a magnetic sensor that includes a magnetoresistance effect element and a magnetic measurement method that can remove 1/f noise using a configuration different from known configurations and measure a small magnetic field with high accuracy.

A magnetic sensor according to an aspect of the invention includes a magnetic detection unit including a magnetoresistance effect element having a pinned magnetic layer, a free magnetic layer, and an intermediate layer formed between the pinned magnetic layer and the free magnetic layer; a magnetic field calculation unit configured to calculate a measurement magnetic field based on an output of the magnetic detection unit, and a saturation magnetic field application unit configured to apply a magnetic field to the free magnetic layer in a direction of the measurement magnetic field to magnetically saturate the free magnetic layer. The magnetic field calculation unit calculates the measurement magnetic field based on a first output of the magnetic detection unit when the measurement magnetic field is applied to the free magnetic layer, and a second output of the magnetic detection unit when the free magnetic layer is magnetically saturated.

The magnetic field calculation unit may calculate the measurement magnetic field based on a difference between the first output and the second output.

The first output contains an output of the measurement magnetic field and 1/f noise, and the second output contains an output in a state in which the free magnetic layer is magnetically saturated and 1/f noise. Accordingly, based on the first output and the second output, 1/f noise can be removed from the first output. For example, by using the difference between the first output and the second output, 1/f noise can be removed from the first output. In addition, the output in the state in which the free magnetic layer is magnetically saturated is known, and thus, based on the first output, the second output, and the known output, a measurement magnetic field obtained by removing 1/f noise from the first output can be obtained.

A magnetization direction of the pinned magnetic layer may be fixed in a first direction, a magnetization direction of the free magnetic layer when the magnetic field is not applied may be orthogonal to the first direction, and the direction of the measurement magnetic field may be parallel or anti-parallel to the first direction.

This configuration enables the relationship between the magnetization direction of the free magnetic layer and the magnetization direction of the pinned magnetic layer to be different depending on the direction of the measurement magnetic field. Accordingly, depending on whether the direction of the measurement magnetic field is parallel or anti-parallel to the first direction, the resistance value of the magnetoresistance effect element changes oppositely. Accordingly, the relationship between the measurement magnetic field and the resistance of the magnetoresistance effect element exhibits odd function characteristics, and thus the direction and magnitude of the measurement magnetic field can be measured.

The magnetoresistance effect element may include a plurality of magnetoresistance effect elements, and the plurality of magnetoresistance effect elements may form a bridge circuit. The use of the bridge circuit that includes a plurality of magnetoresistance effect elements enables a large output corresponding to the measurement magnetic field compared to a case in which a single magnetoresistance effect element is used, thereby increasing the measurement accuracy of the magnetic sensor.

A magnetization direction of the pinned magnetic layer may be fixed in a first direction, a magnetization direction of the free magnetic layer when the magnetic field is not applied may be orthogonal to the first direction, the direction of the measurement magnetic field may be the first direction, and in each of the plurality of magnetoresistance effect elements, a direction in which the magnetic field is applied to the free magnetic layer by the saturation magnetic field application unit may be parallel or anti-parallel to the first direction.

This configuration enables the plurality of magnetoresistance effect elements forming the bridge circuit to have the same resistance value when the free magnetic layers in the magnetoresistance effect elements are saturated. Accordingly, as the second output from the bridge circuit, an output from which the known output in the saturation magnetic field state is removed and contains only 1/f noise can be obtained. In addition, the voltage value obtained from the bridge circuit as the second output is small, and the calculation for determining a measurement magnetic field can be simplified.

The saturation magnetic field application unit may include a coil, a current line, or a magnet. The free magnetic layer can be magnetically saturated by applying a magnetic field by using a coil, a current line, or a magnet.

According to another aspect of the invention, a magnetic measurement method of measuring a measurement magnetic field based on an output of a magnetic detection unit including a magnetoresistance effect element having a pinned magnetic layer, a free magnetic layer, and an intermediate layer formed between the pinned magnetic layer and the free magnetic layer is provided. The magnetic measurement method includes a magnetic field measurement step of obtaining a first output of the magnetic detection unit when the measurement magnetic field is applied, a saturation magnetic field measurement step of obtaining a second output of the magnetic detection unit in a state in which a magnetic field is applied in the direction of the measurement magnetic field and the free magnetic layer is saturated, and a magnetic field calculation step of calculating the measurement magnetic field based on the first output and the second output.

The magnetic field calculation step may calculate the measurement magnetic field based on a difference between the first output and the second output.

By calculating the measurement magnetic field based on the first output obtained in the magnetic field measurement step and the second output obtained in the saturation magnetic field measurement step, the measurement magnetic field from which 1/f noise of the magnetoresistance effect element is removed can be obtained. For example, by using the difference between the first output and the second output, 1/f noise can be removed from the first output.

According to the present invention, 1/f noise can be removed from a measurement magnetic field, and a magnetic sensor and a magnetic measurement method with high magnetic resolution capable of measuring a small magnetic field with high accuracy can be provided.

### BRIEF DESCRIPTION OF THE DRAWINGS

FIG. 1 is a block diagram illustrating a magnetic sensor according to an embodiment;

FIG. 2 is a perspective view schematically illustrating a multilayer structure of a magnetoresistance effect element;

FIG. 3 is a perspective view schematically illustrating a multilayer structure of a magnetoresistance effect element according to a modification;

FIG. 4 is a graph illustrating a relationship between 1/f noise generated in a magnetoresistance effect element and the output of a magnetic detection unit;

FIG. 5A is a flowchart illustrating a magnetic measurement method according to an embodiment;

FIG. 5B is a flowchart illustrating a magnetic measurement method according to one specific example;

FIG. 6 is a schematic view illustrating the magnetic state of a magnetoresistance effect element and the output of a magnetic detection unit in each step in the magnetic measurement method according to an embodiment;

FIG. 7 is a graph illustrating a relationship between a magnetic field applied to a free magnetic layer and the output of a magnetic detection unit;

FIG. 8 illustrates an example operation sequence of a magnetic sensor;

FIG. 9 illustrates another example operation sequence of a magnetic sensor;

FIG. 10 is a diagram illustrating a saturation magnetic field measurement step in the operation sequence illustrated in FIG. 9;

FIG. 11 is a block diagram illustrating a magnetic sensor according to a modification;

FIG. 12 is a block diagram illustrating a full-bridge circuit used as a magnetic detection unit of a magnetic sensor;

FIG. 13 is a block diagram illustrating a state in which a magnetic field is applied to the full-bridge circuit in FIG. 12 and a free magnetic layer is saturated;

FIG. 14A is a graph illustrating a first output in simulation;

FIG. 14B is a graph illustrating a relationship between the frequency of a first output and noise in simulation;

FIG. 15A is a graph illustrating a second output in simulation;

FIG. 15B is a graph illustrating a relationship between the frequency of a second output and noise in simulation;

FIG. 16A is a graph illustrating the output of a measurement magnetic field in simulation;

FIG. 16B is a graph illustrating a relationship between the frequency of the output of a measurement magnetic field and noise in simulation;

FIG. 17 is a block diagram illustrating a modification of a full-bridge circuit;

FIG. 18 is a block diagram illustrating a modification of a full-bridge circuit; and

FIG. 19 is a block diagram illustrating a modification of a full-bridge circuit.

### DESCRIPTION OF THE PREFERRED EMBODIMENTS

Hereinafter, embodiments of the present invention will be described with reference to the attached drawings. In each drawing, the same numerals are applied to the same components, and their descriptions are omitted. Reference coordinates are shown in each drawing as appropriate to indicate the positional relationship of each component.

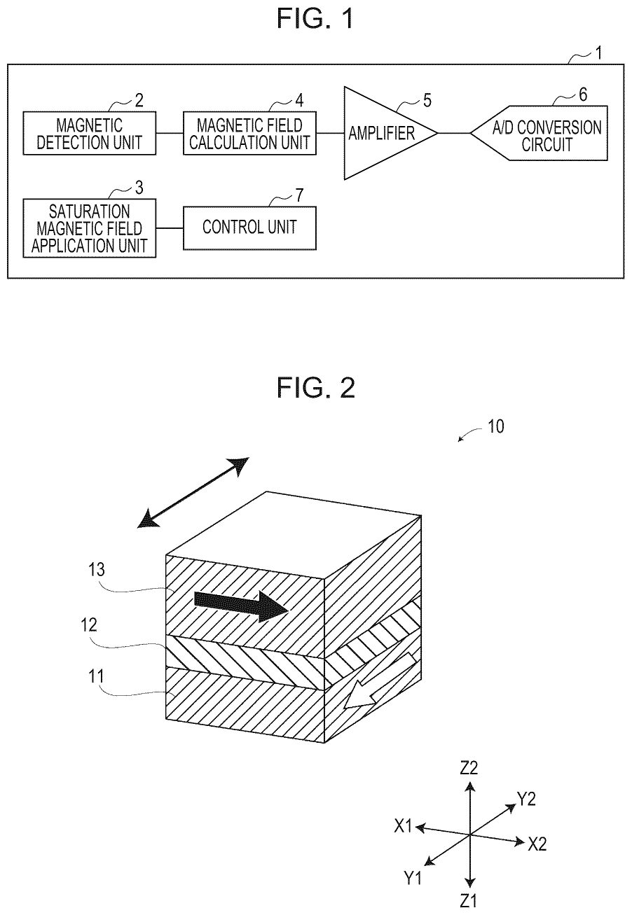

FIG. 1 is a block diagram illustrating a magnetic sensor 1 according to the embodiment. As illustrated in the drawing, the magnetic sensor 1 according to the embodiment includes a magnetic detection unit 2, a saturation magnetic field application unit 3, a magnetic field calculation unit 4, an amplifier 5, an analog-digital conversion circuit 6, and a control unit 7.

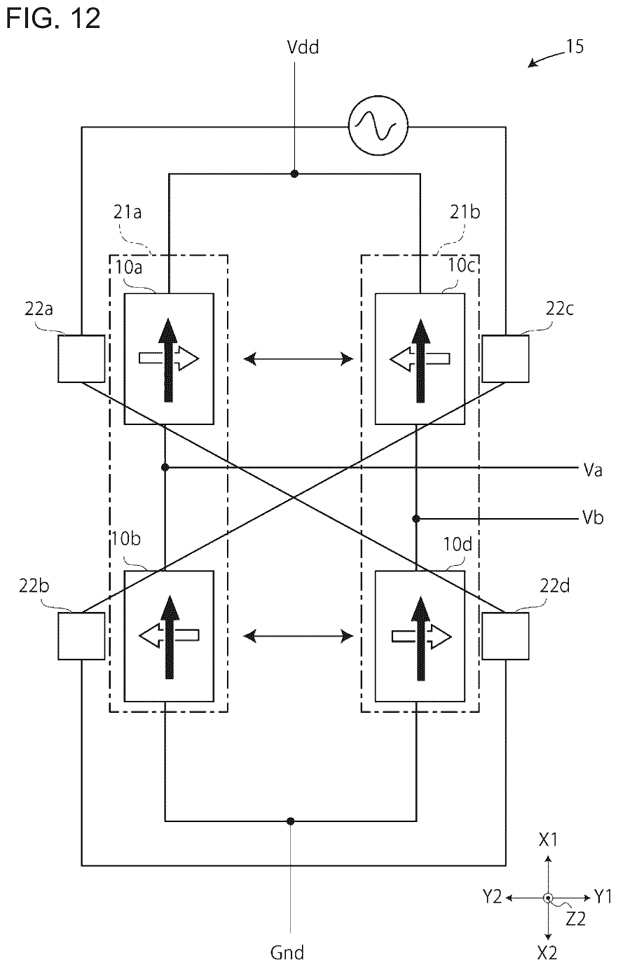

The magnetic detection unit 2 detects an external magnetic field as a measurement target. The magnetic detection unit 2 includes a magnetoresistance effect element 10 (see FIG. 2), a full-bridge circuit 15, half-bridge circuits 21a and 21b (see FIG. 12), which include a plurality of magnetoresistance effect elements 10, or the like.

FIG. 2 is a perspective view schematically illustrating a structure of the magnetoresistance effect element 10 in the magnetic detection unit 2. The magnetoresistance effect element 10 may be, for example, a giant magnetoresistance effect (GMR) element or a tunneling magnetoresistance effect (TMR) element. The magnetoresistance effect element 10 includes a pinned magnetic layer 11, an intermediate layer 12, and a free magnetic layer 13, which are stacked in this order. The resistance value of the magnetoresistance effect element 10 changes depending on the relative relationship between the magnetization direction of the pinned magnetic layer 11, whose magnetization direction is fixed, and the free magnetic layer 13, whose magnetization direction changes depending on an external magnetic field. The magnetic sensor 1 can measure the direction and strength of an external magnetic field to be measured based on a change in the resistance value of the magnetoresistance effect element 10. Hereinafter, the magnetization direction of the pinned magnetic layer 11 is also referred to as a Pin direction as appropriate.

When the magnetoresistance effect element 10 is a GMR element, the pinned magnetic layer 11 comprises a ferromagnetic layer composed of, for example, a cobalt-iron alloy (CoFe alloy). The intermediate layer 12 comprises a non-magnetic intermediate layer composed of, for example, Cu. The free magnetic layer 13 comprises a soft magnetic material such as, a CoFe alloy, a nickel-iron alloy (NiFe alloy), or the like and has a single-layer structure, a multilayer structure, a multilayer ferrimagnetic structure, or the like.

To stabilize the output of the magnetic sensor 1, a bias magnetic field is applied to the free magnetic layer 13 in a direction orthogonal to a direction (in FIG. 2, a Y-axis direction indicated by the double-sided arrow) of a sensitivity axis, which is an external magnetic field (measurement magnetic field) to be measured. This bias magnetic field enables the soft magnetic material in the free magnetic layer 13 to have an aligned magnetization direction when no magnetic field is applied.

The magnetization direction of the pinned magnetic layer 11 in the magnetoresistance effect element 10 is fixed in a first direction (the Y1 direction of the Y axis indicated by the white arrow in FIG. 2). The magnetization direction of the free magnetic layer 13 when no magnetic field is applied is a direction (the X2 direction of the X axis indicated by the black arrow in FIG. 2) orthogonal to the first direction.

Accordingly, the resistance values of the magnetoresistance effect element 10 change in the opposite direction depending on whether the direction of the measurement magnetic field indicated by the double-sided arrow in the drawing is the Y1 direction or the Y2 direction in the Y-axis directions. The signs of the resistance values reverse depending on whether the direction of the measurement magnetic field is the Y1 direction or the Y2 direction on the Y axis, which is the first direction. More specifically, the resistance values exhibit odd function characteristics with respect to the measurement magnetic field, and thus the directions and magnitudes of the measurement magnetic field can be continuously measured.

A TMR element may be used as the magnetoresistance effect element 10 instead of the above-described GMR element. In such a case, the intermediate layer 12 serves as an insulating barrier layer that comprises a material such as MgO, Al₂O₃, titanium oxide, or other similar materials.

The saturation magnetic field application unit 3 illustrated in FIG. 1 applies a magnetic field to the magnetoresistance effect element 10 in the magnetic detection unit 2 to magnetically saturate the free magnetic layer 13. The saturation magnetic field application unit 3 comprises, for example, a coil, a current line, or a magnet. When a TMR element is used as the magnetoresistance effect element 10, a Spin Transfer Torque (STT) can be used instead of a coil, a current line, or a magnet, as a means for saturating the free magnetic layer 13.

The magnetic field calculation unit 4 calculates a measurement magnetic field based on an output of the magnetic detection unit 2, and comprises, for example, a Correlated Double Sampling (CDS) circuit. The magnetic field calculation unit 4 calculates a measurement magnetic field based on a first output when a measurement magnetic field is applied to the free magnetic layer 13 and a second output when the free magnetic layer 13 is magnetically saturated. For example, by taking the difference between the first output and the second output, 1/f noise can be removed from the first output.

In the magnetic sensor 1, after a measurement magnetic field is calculated by the magnetic field calculation unit 4, a signal corresponding to the calculated measurement magnetic field is amplified by the amplifier 5, and the amplified signal is converted into digital data by the analog-digital conversion circuit 6. The control unit 7 controls each component in the magnetic sensor 1, and is a central processing unit (CPU), a program, or the like.

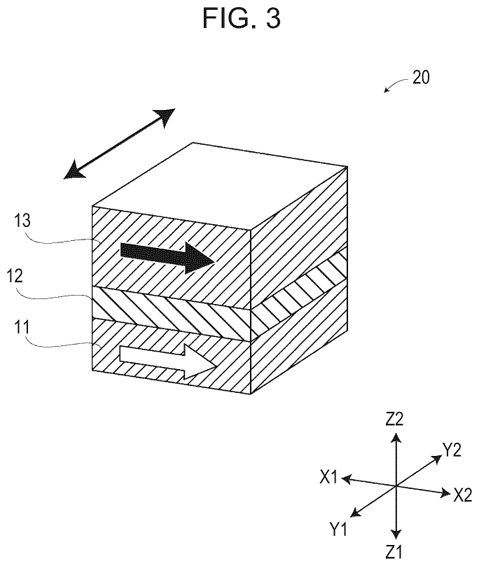

FIG. 3 is a perspective view schematically illustrating a multilayer structure of a magnetoresistance effect element 20 according to a modification. The magnetoresistance effect element 20 illustrated in the drawing is different from the magnetoresistance effect element 10 illustrated in FIG. 2 in the relative relationship between the magnetization direction of the pinned magnetic layer 11 and the magnetization direction of the free magnetic layer 13. More specifically, when no saturation magnetic field is applied to the free magnetic layer 13 of the magnetoresistance effect element 20, the magnetization direction is the X2 direction on the X axis, which is the same as the magnetization direction of the pinned magnetic layer 11.

The resistance values of the magnetoresistance effect element 20 change in the same manner when the direction of the measurement magnetic field indicated by the double-sided arrow in the drawing is the Y1 direction or Y2 direction in the Y-axis directions. More specifically, the resistance values of the magnetoresistance effect element 20 change similarly regardless of the direction of the measurement magnetic field and exhibit even function characteristics with respect to the measurement magnetic field. Accordingly, the magnetoresistance effect element 10 in FIG. 2 is preferable to the magnetoresistance effect element 20 in FIG. 3 in that a larger signal and an output with superior linearity can be obtained.

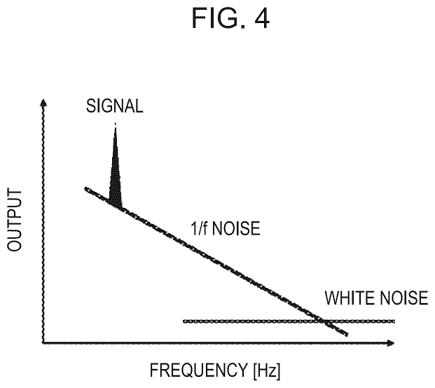

FIG. 4 is a graph illustrating the relationship between 1/f noise generated in the magnetoresistance effect element 10 and the output from the magnetic detection unit 2 that includes one magnetoresistance effect element 10. The 1/f noise contained in the output from the magnetic detection unit 2 increases as the frequency decreases, and low-frequency signals are buried in the 1/f noise. Accordingly, it has been difficult to measure a small magnetic field by using the magnetic sensor 1 that includes the magnetoresistance effect element 10.

The 1/f noise generated in the magnetoresistance effect element 10 can be reduced to some extent by adjusting the physical properties, shape, size, or the like of the materials of each layer. However, it has been difficult to reduce such 1/f noise to near white noise. According to the embodiment of the invention, by using the second output measured in a state in which the free magnetic layer 13 is saturated, 1/f noise can be removed from the first output that contains the measurement magnetic field, thereby enabling a small magnetic field to be measured with high accuracy.

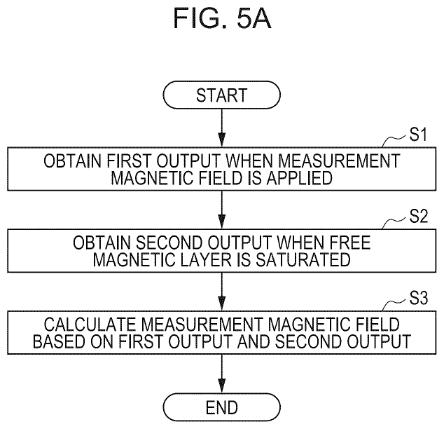

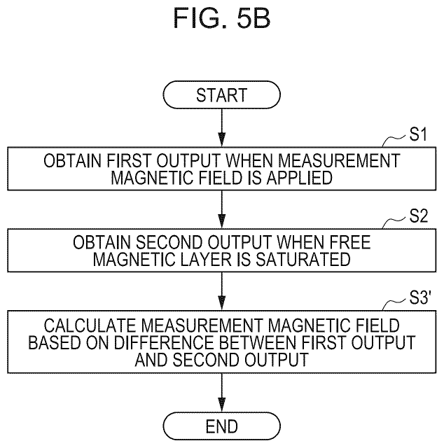

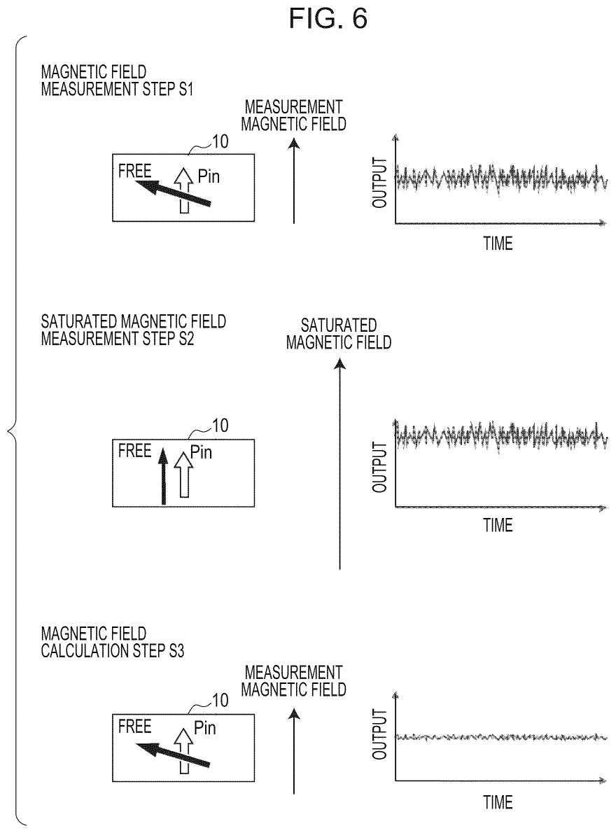

FIG. 5A is a flowchart illustrating a magnetic measurement method according to the embodiment. FIG. 5B is a flowchart illustrating a magnetic measurement method according to one specific example. FIG. 6 is a schematic view illustrating the magnetic state of the magnetoresistance effect element 10 and the output of the magnetic detection unit in each step in the magnetic measurement method according to the embodiment. FIG. 6 illustrates, on the left side, the magnetized state of the pinned magnetic layer 11 and the free magnetic layer 13 in the magnetoresistance effect element 10 in each step, and illustrates, on the right side, the output of the magnetic detection unit 2 (see FIG. 1), which includes one magnetoresistance effect element 10.

As illustrated in FIG. 5A, the magnetic measurement method includes a magnetic field measurement step S1, a saturation magnetic field measurement step S2, and a magnetic field calculation step S3. By measuring an external magnetic field through these steps, 1/f noise is removed from a first output obtained in the magnetic field measurement step S1 and a measurement magnetic field can be obtained. The magnetic measurement method according to the embodiment of the invention can remove 1/f noise, enabling the accurate measurement of a low-frequency, small magnetic field.

Either the magnetic field measurement step S1 or the saturation magnetic field measurement step S2 may be performed first. In the magnetic field calculation step S3, to calculate a measurement magnetic field, the first output obtained in the magnetic field measurement step S1 and the second output obtained in the saturation magnetic field measurement step S2 are used. Accordingly, the magnetic field calculation step S3 is to be performed after the magnetic field measurement step S1 and the saturation magnetic field measurement step S2.

Each of the measurements in the magnetic field measurement step S1 and the saturation magnetic field measurement step S2 may be performed a plurality of times, and based on the plurality of measurement results, the first output and the second output may be calculated. For example, the first output and the second output may be calculated as an average value of a plurality of measurement results obtained by performing a plurality of measurements. In another example, the first output and the second output may be calculated by excluding the maximum value and the minimum value from a plurality of measurement results obtained by performing a plurality of measurements and averaging the remaining measurement results.

In the magnetic field measurement step S1, when a measurement magnetic field is applied to the free magnetic layer 13 (see FIG. 2), a first output of the magnetic detection unit 2 is measured. The first output obtained by the measurement contains a signal of the measurement magnetic field and 1/f noise.

The measurement magnetic field measured in the magnetic field measurement step S1 may be a magnetic field in only one direction or a magnetic field in a plurality of directions. Such a magnetic field in a plurality of directions may be, for example, a magnetic field in the X-axis direction, the Y-axis direction, and the Z-axis direction in a mutually orthogonal XYZ coordinate system. When the magnetic field in a plurality of directions is measured, the measurements may be performed simultaneously or sequentially.

In the saturation magnetic field measurement step S2, in a state in which a magnetic field is applied to the free magnetic layer 13 by the saturation magnetic field application unit 3 and the free magnetic layer 13 is magnetically saturated, a second output of the magnetic detection unit 2 is measured. In the state in which the free magnetic layer 13 is magnetically saturated, the resistance value of the magnetoresistance effect element 10 does not change even if the magnetic field becomes stronger. A saturation magnetic field Hs applied by the saturation magnetic field application unit 3 has a magnitude sufficient to saturate the free magnetic layer 13 and is applied in a direction parallel or anti-parallel to the measurement magnetic field direction.

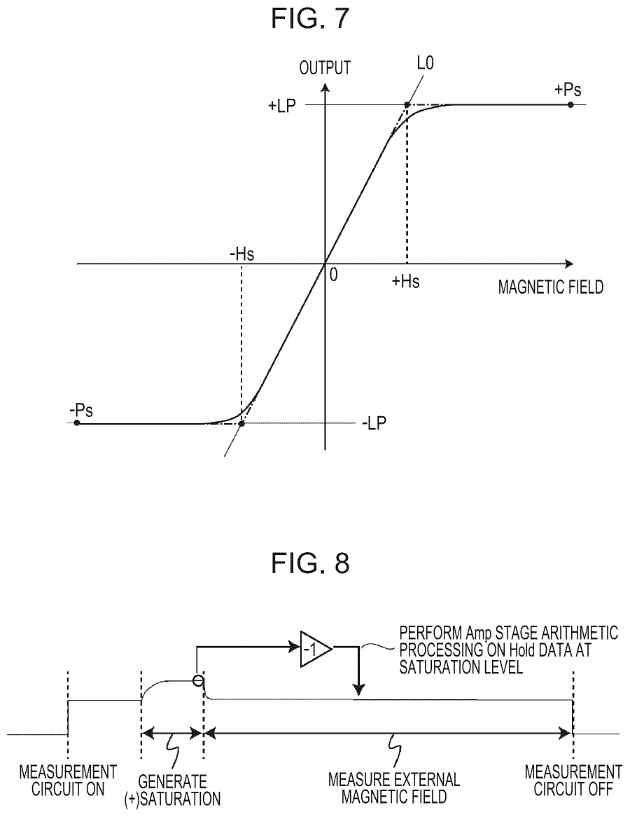

FIG. 7 is a graph illustrating a relationship between a magnetic field applied to the free magnetic layer 13 and the output of the magnetic detection unit 2. The saturation magnetic field Hs that magnetically saturates the free magnetic layer 13 is described with reference to the drawing. Ideally, the output of the magnetic detection unit 2 changes as illustrated by the alternate long and short dashed lines in the drawing until the magnetic field applied to the free magnetic layer 13 becomes the saturation magnetic field +Hs or the saturation magnetic field −Hs, and becomes constant in the range the external magnetic field is greater than or equal to the saturation magnetic field +Hs and in the range the external magnetic field is less than or equal to the saturation magnetic field −Hs. However, in reality, as illustrated by the solid line in the drawing, the output of the magnetic detection unit 2 changes gently around the saturation magnetic field +Hs and the saturation magnetic field −Hs, and changes slightly after the external magnetic field becomes the saturation magnetic field +Hs or the saturation magnetic field −Hs.

In this embodiment, “the free magnetic layer is magnetically saturated” refers to a state in which a magnetic field greater than or equal to the saturation magnetic field +Hs or less than or equal to the saturation magnetic field −Hs, which magnetically saturates the free magnetic layer 13, is applied to the free magnetic layer. Here, the saturation magnetic field Hs refers to a magnetic field at the point where the parallel line +LP from the saturation point +Ps of the output from the magnetic detection unit 2 intersects the tangent line L0 near the zero point where no magnetic field is applied to the free magnetic layer 13, and the saturation magnetic field −Hs refers to a magnetic field at the point where the parallel line −LP from the saturation point −Ps of the output from the magnetic detection unit 2 intersects the tangent line L0.

Even when the free magnetic layer 13 is magnetically saturated, in reality, the magnetic detection unit 2 still has some sensitivity. Accordingly, sensitivity correction (offset correction in the saturation magnetic field measurement step S2 described below) is performed on the magnetic detection unit 2 such that the output is constant in the range greater than or equal to the saturation magnetic field +Hs and in the range less than or equal to the saturation magnetic field −Hs. As illustrated in FIG. 7, the parallel line +LP from the saturation point +Ps and the parallel line −LP from the saturation point −Ps are both parallel to the horizontal axis that indicates the magnitude of the magnetic field.

The second output obtained in the saturation magnetic field measurement step S2 contains a signal (hereinafter, referred to as a saturation magnetic field signal as appropriate) in a state in which the free magnetic layer 13 is magnetically saturated and a signal of 1/f noise. The saturation magnetic field signal is a known signal that is determined by whether a direction in which the free magnetic layer 13 is magnetically saturated is the same direction (parallel) or the opposite direction (anti-parallel) with respect to the Pin direction of the pinned magnetic layer 11. Accordingly, by subtracting the saturation magnetic field signal from the second output obtained in the saturation magnetic field measurement step S2, an output of 1/f noise can be obtained. In this case, the saturation magnetic field signal is an offset signal, and an offset correction is performed to subtract the saturation magnetic field signal from the second output.

In the magnetic field calculation step S3, a measurement magnetic field is calculated based on the first output measured in the magnetic field measurement step S1 and the second output measured in the saturation magnetic field measurement step S2. The first output contains the signal of the measurement magnetic field and 1/f noise, and the second output contains the saturation magnetic field signal and 1/f noise. Accordingly, by using the first output and the second output, the 1/f noise can be removed from the first output.

As described above, the saturation magnetic field signal contained in the second signal is known. Accordingly, by further subtracting the saturation magnetic field signal from the difference between the first output and the second output, a signal of the measurement magnetic field without 1/f noise can obtained.

FIG. 5B is a flowchart illustrating a magnetic measurement method according to one specific example. In the magnetic measurement method illustrated in the drawing, after the magnetic field measurement step S1 and the saturation magnetic field measurement step S2, a magnetic field calculation step S3′ is performed. In the magnetic field calculation step S3′, by calculating the difference between the first output and the second output, 1/f noise is removed from the first output to calculate a measurement magnetic field.

FIG. 8 illustrates an example operation sequence of the magnetic sensor 1, and illustrates a signal output from the magnetic detection unit 2. In the drawing, the order of the magnetic field measurement step S1 and the saturation magnetic field measurement step S2 is reversed from that in the flowchart illustrated in FIG. 5A. After a measurement circuit in the magnetic sensor 1 is turned on, first, as the saturation magnetic field measurement step S2, a magnetic field is applied to the free magnetic layer 13 in the magnetoresistance effect element 10, and in a saturated state, measurement is performed to obtain a second output. Then, as the magnetic field measurement step S1, an external magnetic field is measured without applying the magnetic field for saturating the free magnetic layer 13 to obtain a first output. Then, the magnetic field calculation step S3 is performed, and based on the first output and the second output, an external magnetic field from which 1/f noise is removed, that is, the measurement magnetic field, is calculated.

In FIG. 8, the free magnetic layer 13 is saturated in the (+)direction; however, alternatively, in a state in which the free magnetic layer 13 is saturated in the (−)direction, the saturation magnetic field measurement step S2 may be performed. Here, the state in which saturated in the (+)direction refers to a state in which the free magnetic layer 13 is saturated by applying a magnetic field in the same direction (parallel) as the Pin direction, and is also referred to as (+)saturation as appropriate. The state in which saturated in the (−)direction refers to a state in which the free magnetic layer 13 is saturated by applying a magnetic field in the opposite direction (anti-parallel) to the Pin direction, and is also referred to as (−)saturation as appropriate.

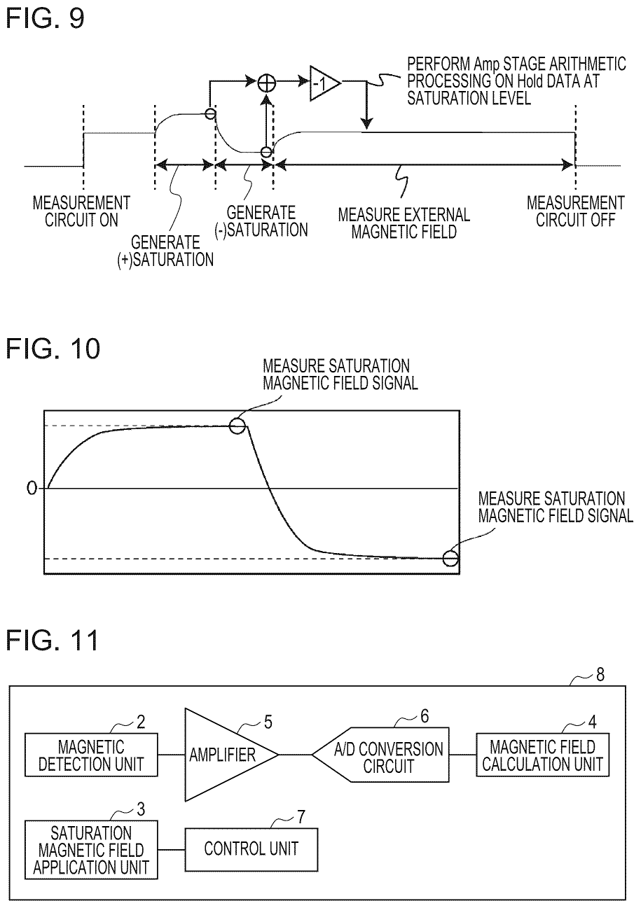

FIG. 9 illustrates another example operation sequence of the magnetic sensor 1. In the operation sequence illustrated in the drawing, in the saturation magnetic field measurement step S2, the free magnetic layer in the magnetoresistance effect element is saturated in both the (+)direction and the (−)direction, measurement is performed in the two states, that is, the (+)saturation and the (−)saturation, and a second output is obtained by using the two obtained measurement results.

FIG. 10 is a diagram illustrating the saturation magnetic field measurement step S2 in the operation sequence illustrated in FIG. 9. In FIG. 10, first, the free magnetic layer 13 in the magnetoresistance effect element 10 is brought into the (+)saturated state and measured, and then brought into the (−)saturated state and measured. The absolute values of signal strength of the saturation magnetic field signals are large, and accordingly, in the measurement results in the saturated states containing the saturation magnetic field signals, the absolute values of signal strength are large in both the (+)saturated state and the (−)saturated state. However, the saturation magnetic field signal in the (+)saturation measurement result and the saturation magnetic field signal in the (−)saturation measurement result have opposite polarities, and accordingly, the absolute value of the signal strength can be reduced by adding these measurement results to obtain a second output or by using the average value of the measurement results to obtain a second output. This operation enables the absolute value of the signal strength to be processed in the magnetic field calculation unit 4, the amplifier 5, and the analog-digital conversion circuit 6 (A/D conversion circuit, see FIG. 1) to be reduced, which is advantageous from the viewpoint of increasing the gain of the amplifier and increasing the resolution during A/D conversion.

By using the measurement results in the (+)saturation and (−)saturation states as described above, the absolute value of the signal strength of the second output can be reduced. It should be noted that the second output may contain an offset signal due to variations in the magnetoresistance effect element 10. If the second output contains such an offset signal, offset correction is performed to remove the offset signal.

FIG. 11 is a block diagram illustrating a magnetic sensor 8 according to a modification. In the magnetic sensor 8 according to the modification, a first output and a second output from the magnetic detection unit 2 are amplified by the amplifier 5, subjected to A/D conversion in the analog-digital conversion circuit 6 to have digital signals, and then a measurement magnetic field is calculated in the magnetic field calculation unit 4. These units in the magnetic sensor are each configured to calculate a measurement magnetic field based on a first output and a second output, and not limited to the examples illustrated in FIG. 1 and FIG. 11.

FIG. 12 is a schematic view illustrating the full-bridge circuit 15 used as the magnetic detection unit 2 (see FIG. 1) in the magnetic sensor 1. As illustrated in the drawing, the full-bridge circuit 15 includes magnetoresistance effect elements 10a, 10b, 10c, and 10d (when these elements are not distinguished, they are referred to as magnetoresistance effect elements 10 as appropriate). The four magnetoresistance effect elements 10 may be provided on the same substrate (one chip).

The full-bridge circuit 15 includes the half-bridge circuit 21a and the half-bridge circuit 21b connected in parallel between a power supply terminal Vdd, which is a power supply feeding point, and a ground terminal Gnd. The half-bridge circuit 21a includes the magnetoresistance effect elements 10a and 10b connected in series, and the half-bridge circuit 21b includes the magnetoresistance effect elements 10c and 10d connected in series.

The half-bridge circuit 21a includes an output terminal Va between the magnetoresistance effect element 10a and the magnetoresistance effect element 10b. The half-bridge circuit 21b includes an output terminal Vb between the magnetoresistance effect element 10c and the magnetoresistance effect element 10d. Based on a potential difference (Va−Vb, midpoint potential difference) of outputs of these two output terminals Va and Vb, the magnitude of an external magnetic field externally applied as a measurement magnetic field can be quantitatively measured.

The pair of magnetoresistance effect elements 10a and 10b forming the half-bridge circuit 21a include the pinned magnetic layers 11 that have magnetization directions (Pin directions) in the Y1 direction and the Y2 direction, respectively. The pair of magnetoresistance effect elements 10c and 10d forming the half-bridge circuit 21b include the pinned magnetic layers 11 that have magnetization directions (Pin directions) in the Y2 direction and the Y1 direction, respectively.

In the half-bridge circuit 21a and the half-bridge circuit 21b, the Pin directions of the magnetoresistance effect elements 10a and 10c on the power supply terminal Vdd side are opposite (anti-parallel). The Pin directions of the magnetoresistance effect elements 10b and 10d on the ground terminal Gnd side are opposite (anti-parallel).

The magnetization directions of the free magnetic layers 13 in the four magnetoresistance effect elements 10a, 10b, 10c, and 10d are the same X1 direction in a state in which no external magnetic field is applied.

With the above-described configuration, as the magnitude of the measurement magnetic field in the Y-axis direction changes, the output from the output terminal Va from the half-bridge circuit 21a and the output from the output terminal Vb from the half-bridge circuit 21b change in opposite directions. As a result, a large output can be obtained as a potential difference between the two output terminals Va and Vb. Accordingly, by using the full-bridge circuit 15 as the magnetic detection unit 2, the measurement magnetic field can be detected with high accuracy. It should be noted that instead of the full-bridge circuit 15, the half-bridge circuits 21a and 21b or the magnetoresistance effect elements 10 can be used as the magnetic detection unit 2.

In the vicinity of the magnetoresistance effect elements 10a, 10b, 10c, and 10d, saturation magnetic field application units 22a, 22b, 22c, and 22d that apply magnetic fields to the free magnetic layers 13 (see FIG. 2) are provided respectively. Each of the saturation magnetic field application units 22a, 22b, 22c, and 22d includes, for example, a coil, a current line, or a magnet. In FIG. 12, the saturation magnetic field application units 22a, 22b, 22c, and 22d are connected such that saturation magnetic fields in the same direction can be applied to the magnetoresistance effect element 10a and the magnetoresistance effect element 10c, and saturation magnetic fields in the direction opposite to the direction in the magnetoresistance effect element 10a can be equally applied to the magnetoresistance effect element 10b and the magnetoresistance effect element 10d.

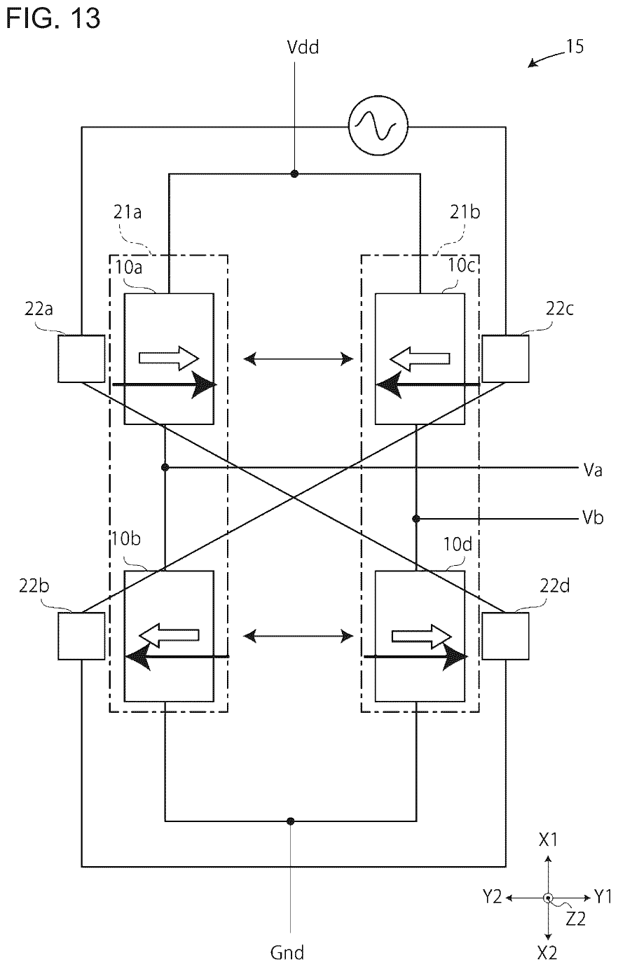

FIG. 13 is a block diagram illustrating the full-bridge circuit 15 in a state in which saturation magnetic fields are applied to the magnetic sensor 1 in FIG. 12 and the free magnetic layers 13 are saturated. In the example illustrated in the drawing, the free magnetic layers 13 in the magnetoresistance effect elements 10a, 10b, 10c, and 10d are saturated in directions parallel to the magnetization directions of the pinned magnetic layers 11. Accordingly, the resistance values of the magnetoresistance effect elements 10a, 10b, 10c, and 10d are equal.

The half-bridge circuit 21a and the half-bridge circuit 21b in the full-bridge circuit 15 include the magnetoresistance effect elements 10 that have the same relative relationship in the magnetization directions of the free magnetic layer 13 and the pinned magnetic layer 11 in a state in which the free magnetic layers 13 are magnetically saturated. Accordingly, the second output obtained based on the outputs from the output terminals Va and Vb contains no saturation magnetic field signal but contains only 1/f noise. The measurement magnetic field can be obtained, accordingly, based only on the first output and the second output without using a known saturation magnetic field signal in the state in which the free magnetic layers 13 are saturated. In addition, the magnetoresistance effect elements 10 in the state in which the free magnetic layers 13 are saturated have the same resistance values, and the full-bridge circuit 15 have an output of a small value, thereby facilitating subsequent signal processing.

### Simulation

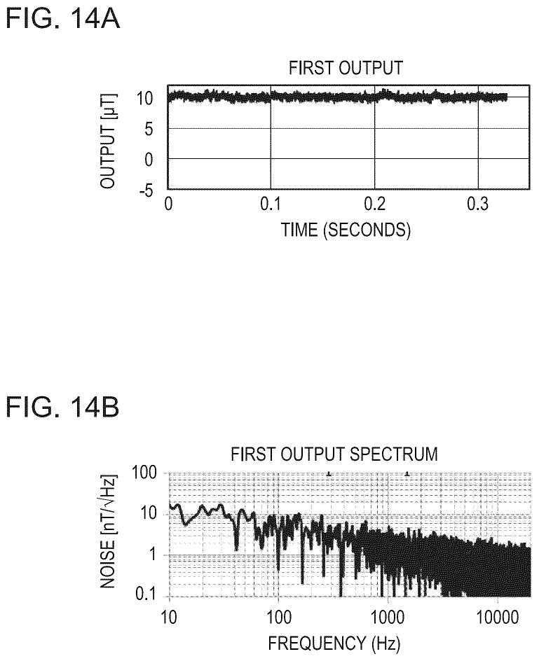

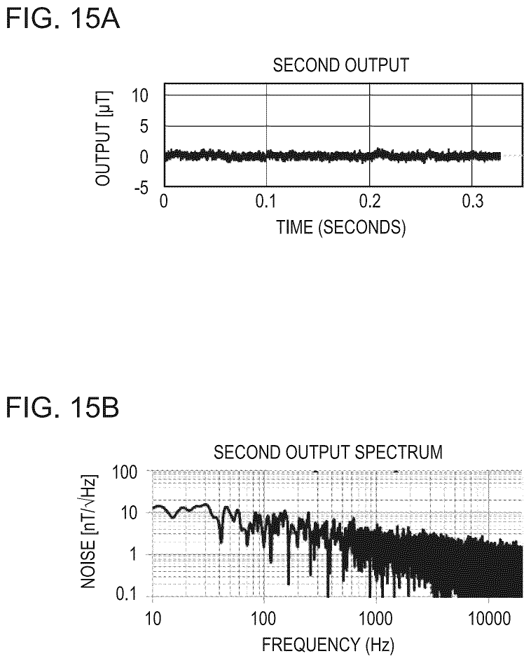

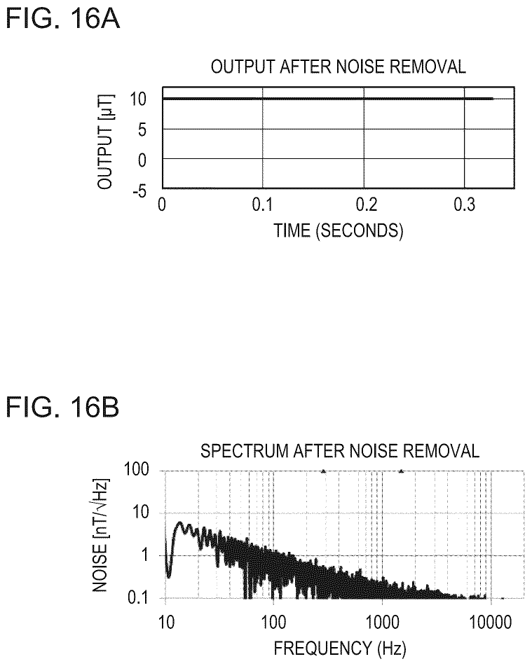

A simulation was performed on the magnetic sensor 1 including the full-bridge circuit 15 having the four magnetoresistance effect elements 10 illustrated in FIG. 13. FIG. 14A and FIG. 14B are a graph illustrating the first output obtained by the simulation and a graph illustrating the relationship between the frequency and noise. FIG. 15A and FIG. 15B are a graph illustrating the second output obtained by the simulation and a graph illustrating the relationship between the frequency and noise. FIG. 16A and FIG. 16B are a graph illustrating the output based on a first output and a second output according to the embodiment and a graph illustrating the relationship between the frequency and noise in the output.

As illustrated in FIG. 15A, the second output was obtained as a signal having the signal strength of small absolute values. This means that the saturation magnetic field signal was canceled in the second output in the state in which the free magnetic layers 13 in the magnetoresistance effect elements 10 in the full-bridge circuit 15 were saturated.

In an ideal state in which the magnetoresistance effect elements 10a, 10b, 10c, and 10d in the full-bridge circuit 15 are completely the same except the Pin directions and the directions in which saturation magnetic fields are applied, the second output contains only 1/f noise but contains no saturation magnetic field signal. However, when the magnetoresistance effect elements 10a, 10b, 10c, and 10d have variations, the second output from the full-bridge circuit 15 contains an offset signal due to the variations in addition to 1/f noise. If the second output contains such an offset signal, offset correction is performed to remove the offset signal.

As illustrated in FIG. 16A, by taking the difference between the first output illustrated in FIG. 14A and the second output illustrated in FIG. 15A, the measurement magnetic field with less noise can be obtained. As illustrated in FIG. 16B, compared to the spectrum of the first output illustrated in FIG. 14B, the spectrum after noise removal has reduced noise overall, including noise components in the low frequency range. According to the embodiment of the present invention, therefore, 1/f noise contained in a measurement magnetic field can be reduced.

### Modifications

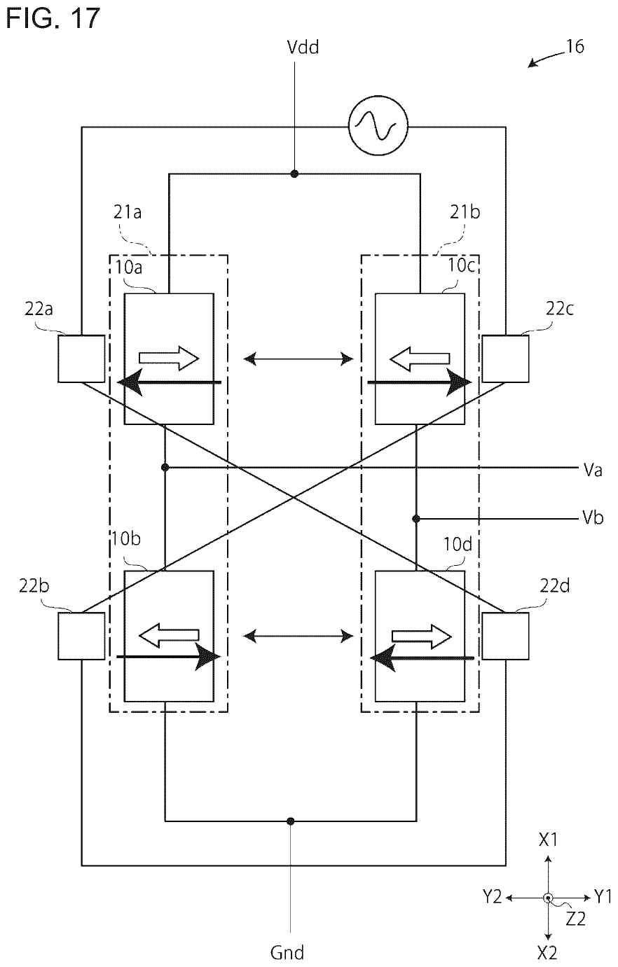

FIG. 17 is a block diagram illustrating a full-bridge circuit 16 according to a modification in a state in which the free magnetic layers 13 in FIG. 13 are saturated. In the example illustrated in the drawing, the free magnetic layers 13 in the magnetoresistance effect elements 10a, 10b, 10c, and 10d are saturated in directions anti-parallel to the magnetization directions of the pinned magnetic layers 11.

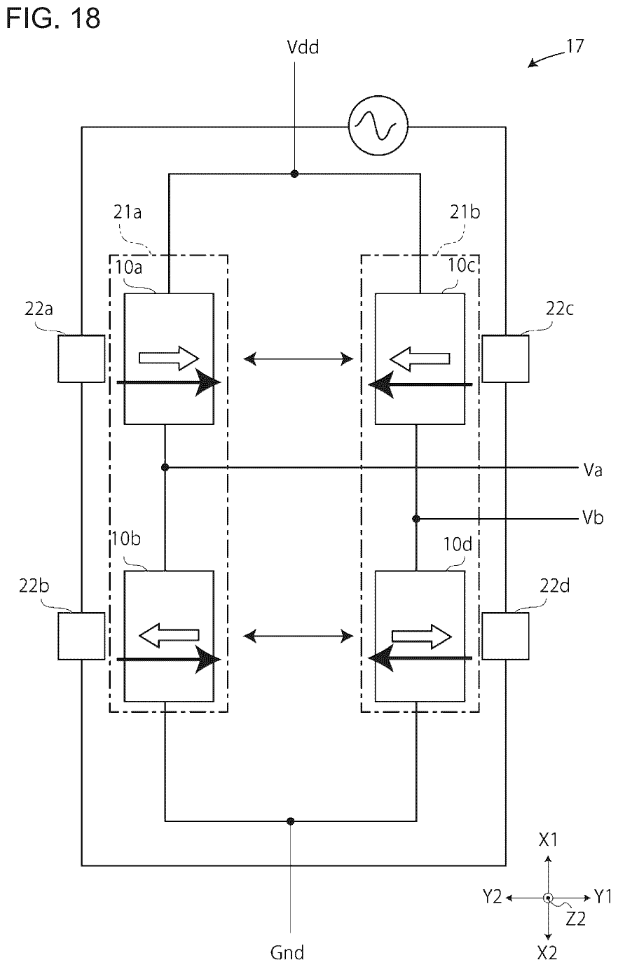

FIG. 18 is a block diagram illustrating a full-bridge circuit 17 according to a modification. In the example illustrated in the drawing, the free magnetic layers 13 in the magnetoresistance effect elements 10a and 10c are saturated in directions parallel to the magnetization directions of the pinned magnetic layers 11, and the free magnetic layers 13 in the magnetoresistance effect elements 10b and 10d are saturated in directions anti-parallel to the magnetization directions of the pinned magnetic layers 11. To achieve this configuration, the full-bridge circuit 17 employs a connection method for the saturation magnetic field application units 22a, 22b, 22c, and 22d, which is different from the connection method in the full-bridge circuit 15.

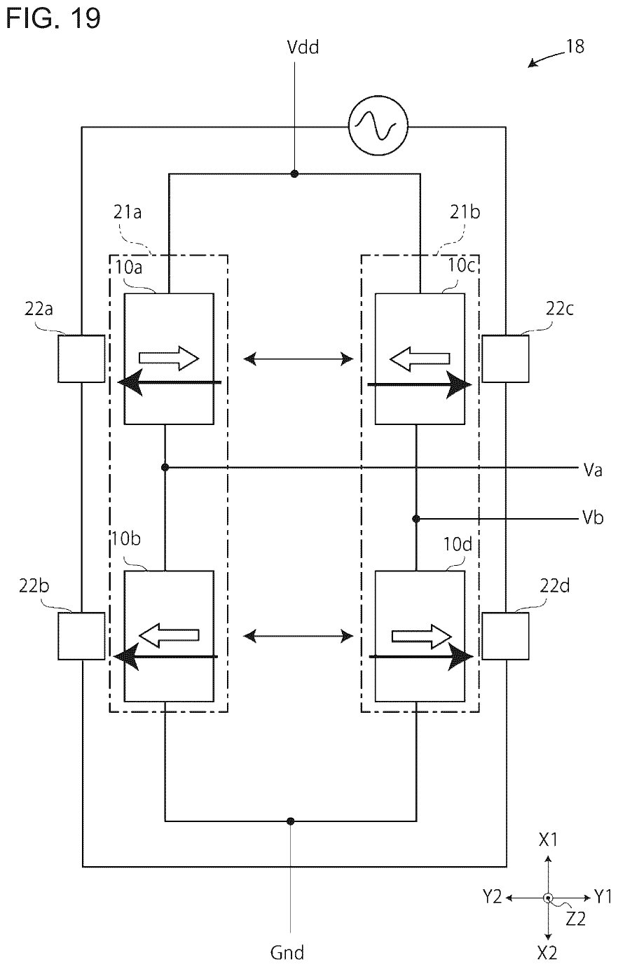

FIG. 19 is a block diagram illustrating a full-bridge circuit 18 according to a modification. The full-bridge circuit 18 according to the example has the same configuration as the full-bridge circuit 17 as a circuit, but the direction of power supply to the saturation magnetic field application units 22a, 22b, 22c, and 22d is opposite. With this configuration, the free magnetic layers 13 in the magnetoresistance effect elements 10a and 10c are saturated in directions anti-parallel to the magnetization directions of the pinned magnetic layers 11. In addition, the free magnetic layers 13 in the magnetoresistance effect elements 10b and 10d are saturated in directions parallel to the magnetization directions of the pinned magnetic layers 11.

The full-bridge circuits 16 to 18 according to the modifications illustrated in FIG. 17 to FIG. 19 also include the half-bridge circuit 21a and the half-bridge circuit 21b that include the magnetoresistance effect elements 10 in which the relative magnetization directions between the free magnetic layers 13 and the pinned magnetic layers 11 in a state in which the free magnetic layers 13 are magnetically saturated are the same. Accordingly, similarly to the full-bridge circuit 15 in FIG. 13, outputs from the output terminal Va and the output terminal Vb contain no saturation magnetic field signal. Therefore, as the differences between the outputs from the output terminals Va and Vb, the second outputs that contain no saturation magnetic field signal in a state in which the free magnetic layers 13 are saturated and contain 1/f noise can be obtained.

The embodiments disclosed in this specification are in all respects illustrative and not limited to these embodiments. The scope of the invention is defined by the claims, but is not defined by the description of only the above embodiments, and is intended to include all modifications within the meaning and scope equivalent to the claims. For example, in the above description, a saturation magnetic field is applied to the magnetoresistance effect elements 10a, 10b, 10c, and 10d by the saturation magnetic field application units 22a, 22b, 22c, and 22d; however, this configuration is not limited to this example. For example, when the magnetic sensor 1 is used to measure an induction field generated by a current to be measured that is flowing in a current line provided in the vicinity of the magnetic sensor 1, a large current may be applied to this current line to generate an induction field for magnetically saturating the free magnetic layers 13.

1. A magnetic sensor comprising:
a magnetic detection unit including at least one magnetoresistance effect element having:
a pinned magnetic layer;
a free magnetic layer; and
an intermediate layer formed between the pinned magnetic layer and the free magnetic layer;
a magnetic field calculation unit configured to calculate a measurement magnetic field based on an output of the magnetic detection unit; and
a saturation magnetic field application unit configured to apply a magnetic field to the free magnetic layer in a direction of the measurement magnetic field, thereby magnetically saturating the free magnetic layer,
wherein the magnetic field calculation unit calculates the measurement magnetic field based on a first output of the magnetic detection unit when the measurement magnetic field is applied to the free magnetic layer, and a second output of the magnetic detection unit when the free magnetic layer is magnetically saturated.

2. The magnetic sensor according to claim 1, wherein the magnetic field calculation unit calculates the measurement magnetic field based on a difference between the first output and the second output.

3. The magnetic sensor according to claim 1,
wherein the pinned magnetic layer has a fixed magnetization direction in a first direction, and the free magnetic layer has a magnetization direction orthogonal to the first direction when the magnetic field is not applied thereto,
and wherein the direction of the measurement magnetic field is parallel or anti-parallel to the first direction.

4. The magnetic sensor according to claim 1, wherein the at least one magnetoresistance effect element includes a plurality of magnetoresistance effect elements, and the plurality of magnetoresistance effect elements form a bridge circuit.

5. The magnetic sensor according to claim 4,
wherein the pinned magnetic layer has a fixed magnetization direction in a first direction, and the free magnetic layer has a magnetization direction orthogonal to the first direction when the magnetic field is not applied thereto,
wherein the direction of the measurement magnetic field is the first direction,
and wherein the saturation magnetic field application unit is configured to apply the magnetic field to the free magnetic layer of each of the plurality of magnetoresistance effect elements in a direction parallel or anti-parallel to the first direction.

6. The magnetic sensor according to claim 1, wherein the saturation magnetic field application unit includes a coil, a current line, or a magnet.

7. A method of measuring a measurement magnetic field with a magnetic detection unit including a magnetoresistance effect element having a pinned magnetic layer, a free magnetic layer, and an intermediate layer formed between the pinned magnetic layer and the free magnetic layer, the method comprising:
obtaining a first output from the magnetic detection unit by applying the measurement magnetic field thereto;
obtaining a second output from the magnetic detection unit by applying a magnetic field thereto in the direction of the measurement magnetic field such that the free magnetic layer is magnetically saturated; and
calculating the measurement magnetic field based on the first output and the second output.

8. The magnetic measurement method according to claim 7, wherein the measurement magnetic field is calculated based on a difference between the first output and the second output.
